(19) United States
(12) Patent Application Publication
(10) Pub. No.: US 2026/0262536 A1
(43) Pub. Date: Sep. 3, 2026

(54) POWER SEMICONDUCTOR PACKAGE STRUCTURE

(71) Applicant: CAMBRIDGE INTEGRATION LTD, Cambridge (GB)

(72) Inventors: Ameer Hussein Abd JANABI, Cambridge (GB); Teng LONG, Beijing (CN)

(73) Assignee: CAMBRIDGE INTEGRATION LTD, Cambridge (GB)

(21) Appl. No.: 19/555,287

(22) Filed: Mar. 3, 2026

(30) Foreign Application Priority Data
Mar. 3, 2025 (CN) 202510240714.8
Mar. 3, 2025 (CN) 202520351255.6

(51) Int. Cl. H10W 74/10

(52) U.S. Cl. CPC H10W 74/114

(57) ABSTRACT

A power semiconductor package structure, base plate, power semiconductor chip, PCB plate, package sealing layer. Upper conductive metal layer of base plate includes left metal layer and right metal layer separated by slot and electrically isolated. Sunken left mounting platform disposed on side of left metal layer close to separation slot. A sunken right mounting platform is disposed in middle part of right metal layer. Right mounting platform is configured for disposing chip, PCB plate is mounted on left and right mounting platform. A drain of chip is interconnected with right mounting platform; left metal layer is connected to source of chip through PCB plate, an extension part configured to connect to external driver circuit of power semiconductor package structure is disposed on an edge of PCB plate on a side of right metal layer, the extension part connects gate and source of chip to external driver circuit.

### TECHNICAL FIELD

The present disclosure relates to the field of semiconductor device technologies, and specifically, to a power semiconductor package structure.

### BACKGROUND

Power semiconductor packages are a type of industrial products that enable power semiconductor chips to be electrically connected to external circuit boards and thermally conductively connected to external heat sinks while protecting the power semiconductor chips. The power semiconductor package needs to have the following functions: providing an electrical contact with a semiconductor chip, which is usually achieved through a bonding wire, to ensure connection to an electrical interface outside the package; providing sufficient connection between a heat sink and a path of a cooling system, so that the heat sink and the path of the cooling system can dissipate heat losses of hundreds or thousands of watts; and protecting the semiconductor from environmental impact, especially humidity.

There are a variety of existing power semiconductor package structures. For example, a power semiconductor package structure of a MOSFET chip disclosed in CN219435850U includes a package housing and a silicon chip disposed in the package housing. A plurality of copper strips adhered to the top of the silicon chip, a source pin and a gate pin respectively adhered to one end of different copper strips, a drain pin adhered to the bottom of the silicon chip, and a thermal conductive bottom plate connected to the bottom of the drain pin are further disposed in the package housing. A metal housing wraps and is adhered to the package housing. Heat is conducted to a base of a PCB through the drain pin and the thermal bottom plate. This provides more contact area for heat dissipation, to carry away heat from the silicon chip. In addition, through the arrangement of the metal housing on the package housing to wrap an extension end of the drain pin, heat can also be conducted to the metal housing, and then dissipated through the metal housing, thereby improving the heat dissipation effect. This can still meet the heat dissipation requirement when a current requirement increases, thereby avoiding thermal saturation of the PCB.

In a process of preparing the power semiconductor device package structure disclosed in CN110676176B, by disposing a flexible conductive layer and an insulation board with conductive layers covering on both sides, an E electrode does not directly act on a chip component, a current of the chip component reaches the E electrode through the flexible conductive layer, heat of the chip component is conducted to a heat dissipation working medium through the flexible conductive layer in a perpendicular manner (for example, heat is transferred to surrounding electrodes). In addition, a first conduction protrusion contacts the flexible conductive layer, to distribute a compressive stress acting on the chip component, so that the flexible conductive layer implements a small compressive stress on a soldering surface of the chip component, thereby avoiding a large compressive force from directly acting on the surface of the chip component. Three-way stress damage under a high-pressure stress condition during temperature cycles of the chip component is reduced, connection reliability is improved, pressure is decoupled from electrical and thermal conduction, and reliability of the power semiconductor device package structure is finally improved.

A power semiconductor device package architecture disclosed in CN114551378A belongs to the technical field of semiconductor power device mounting structures, and at least resolves a technical problem in which a structure disposed in a leadless manner causes low efficiency of heat dissipation of a power device in the existing technology. The package architecture includes a package container and a heat sink partially embedded in a top of the package container, a heat dissipation component is disposed in the encapsulation container, and the heat dissipation component can clamp or wrap the power device, conduct to the power device, and contact with the heat sink. Heat generated during operating of the power device is transferred to the heat sink through heat conduction by using the heat dissipation component, to reduce the temperature of the power device or dissipate heat.

### SUMMARY

A technical problem to be resolved in the present invention is to provide a power semiconductor package structure having stable performance and good heat sink performance.

To resolve the foregoing technical problem, a technical solution used in the present invention is to provide a power semiconductor package structure, including a base plate, a power semiconductor chip, and an interconnection printed circuit board (PCB) connecting corresponding parts on the power semiconductor chip and the base plate; where a package sealing layer wrapping the power semiconductor chip and the interconnection PCB is disposed on the base plate.

The base plate includes an intermediate insulation layer, an upper conductive metal layer of the base plate, and a lower conductive metal layer of the base plate; the lower conductive metal layer of the base plate is configured to connect to a heat sink; the upper conductive metal layer of the base plate includes a left metal layer and a right metal layer that are physically separated by a separation slot and are electrically isolated; a sunken left mounting platform is disposed on a side of the left metal layer close to the separation slot, a sunken right mounting platform is disposed in a middle part of the right metal layer, the right mounting platform is configured for disposing the power semiconductor chip, and the interconnection PCB is mounted on the left mounting platform and the right mounting platform.

A drain of the power semiconductor chip is located at a bottom of the power semiconductor chip, and a source and a gate of the power semiconductor chip are located at a top of the power semiconductor chip; the drain of the power semiconductor chip is interconnected with the right mounting platform; the left metal layer is connected to the source of the power semiconductor chip through the interconnection PCB, an extension part configured to connect to an external driver circuit of the power semiconductor package structure is disposed on an edge of the interconnection PCB on a side close to the right metal layer, and the extension part connects the source and the gate of the power semiconductor chip to the external driver circuit.

The interconnection PCB includes an insulating substrate, a base plate connection part is disposed on a back side of the interconnection PCB, the base plate connection part is electrically connected to the left mounting platform on the base plate, and a relatively high surface of a copper layer of the left metal layer is used as an external interface of the power semiconductor package structure; and a power semiconductor chip connection part interconnected with the source of the power semiconductor chip is disposed on the back side of the interconnection PCB.

A base plate correspondence part on a front side and the base plate connection part on the back side of the interconnection PCB are electrically connected to each other through a plurality of first conductive vias; a gate connection part connected to the gate is disposed on the back side of the interconnection PCB, and a chip correspondence part on the front side and a power semiconductor chip connection part on the back side of the interconnection PCB are electrically connected to each other through a plurality of second conductive vias.

A protrusion part of the interconnection PCB and top surfaces of the left metal layer and the right metal layer on two distal ends of the base plate are exposed out of the package sealing layer to interconnect with an external main circuit.

In a preferred solution, a plurality of adhesive pouring holes that run through a thickness direction of the interconnection PCB to allow a sealing material of the package sealing layer to penetrate into free space below the interconnection PCB during packaging are disposed on the interconnection PCB.

In a preferred solution, a back side conduction part that conducts to the gate connection part and a front side conduction part that conducts to a source connection part are disposed on the extension part.

The present invention has the following beneficial effects:

According to the package structure, a parasite induction of the package can be counterbalanced to be very low. A parasite parameter in the power semiconductor package is reduced, and high-frequency performance of the circuit is improved. In addition, the design of negative coupling between the chip and the direct current bus further reduces the parasite induction. Sealing and protection of the chip is implemented through injection or silicon packaging, to prevent invasion of humidity and other environmental factors.

The flexible PCB is designed with a plurality of through-holes that run through a thickness direction of the interconnection PCB to allow a sealing material of the package sealing layer to penetrate into free space below the interconnection PCB during packaging, so that the sealing material can better penetrate, and the structure after packaging becomes stronger, thereby further ensuring use reliability, and improving sealing performance and an electrical isolation effect.

In this structure, the chip mounting recess and the electrical connection area can be directly formed by using a step etching process, thereby reducing complexity of multi-step processing in conventional packaging. In addition, a connection process such as silver sintering or soldering is used, to provide a reliable and highly efficient assembly method.

The flexible PCB of this structure provides a stress relieving function, and effectively reduces impact of thermal expansion or mechanical vibration on chip connection. In addition, a high thermal conduction isolation substrate such as DBC or AMB may be used, thereby effectively reducing thermal resistance during operating of the device. The step etching design ensures that the chip is in close contact with the substrate, thereby optimizing a heat conduction path.

### BRIEF DESCRIPTION OF THE DRAWINGS

FIG. 1 is a schematic diagram of an internal structure of a power semiconductor package structure;

FIG. 2 is a schematic structural diagram of a power semiconductor chip;

FIG. 3 is a schematic structural diagram of an interconnection printed circuit board (PCB);

FIG. 4 is a schematic structural diagram of a power semiconductor package structure connected to a circuit board of a main circuit; and

FIG. 5 is a schematic overall view of a power semiconductor package structure after packaging.

In the figure: power semiconductor package structure 100, base plate 200, power semiconductor chip 300, interconnection PCB 400, package sealing layer 600; upper conductive metal layer 201 of the base plate, intermediate insulation layer 202, lower conductive metal layer 203 of the base plate, right mounting platform 204, separation slot 205, right metal layer 206, left metal layer 207, left mounting platform 208; source 301, gate 302, drain 303; extension part 401, insulating substrate 402; base plate correspondence part 410, chip correspondence part 411, front side conduction part 412, adhesive pouring hole 413; base plate connection part 420, first conductive via 421, power semiconductor chip connection part 422, gate connection part 423, back side conduction part 424.

### DETAILED DESCRIPTION

The following describes specific implementation solutions of the present invention in detail with reference to the accompanying drawings.

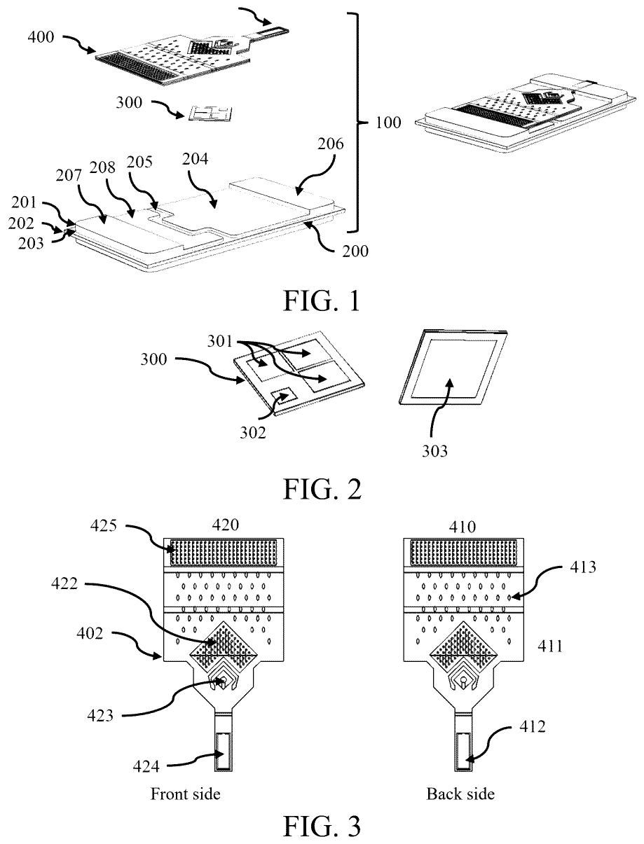

As shown in FIG. 1 to FIG. 5, a power semiconductor package structure 100 includes a base plate 200, a power semiconductor chip 300, and an interconnection printed circuit board (PCB) 400 connecting corresponding parts on the power semiconductor chip 300 and the base plate 200; where a package sealing layer 600 wrapping the power semiconductor chip 300 and the interconnection PCB 400 is disposed on the base plate.

As shown in FIG. 1, the base plate 200 includes an intermediate insulation layer 202, an upper conductive metal layer 201 of the base plate, and a lower conductive metal layer 203 of the base plate, the lower conductive metal layer 203 of the base plate is configured to connect to a heat sink, the power semiconductor chip 300 is disposed on the upper conductive metal layer 201 of the base plate, and the upper conductive metal layer 201 of the base plate is used as a part of electrical connection to connect the power semiconductor chip 300 and another circuit board or conductor.

The upper conductive metal layer 201 of the base plate includes a left metal layer 207 and a right metal layer 206 that are physically separated by a separation slot 205 and are electrically isolated; a sunken left mounting platform 208 is disposed on a side of the left metal layer 207 close to the separation slot 205, a sunken right mounting platform 204 is disposed in a middle part of the right metal layer 206, the right mounting platform 204 is configured for disposing the power semiconductor chip 300, and the interconnection PCB 400 is mounted on the left mounting platform 208 and the right mounting platform 204; and the drain 303 of the power semiconductor chip is interconnected with the right mounting platform 204.

As shown in FIG. 2, the drain 303 of the power semiconductor chip 300 is located at a bottom of the power semiconductor chip 300, and a source 301 and a gate 302 of the power semiconductor chip 300 are located at a top of the power semiconductor chip 300.

The left metal layer 207 is connected to the source 301 of the power semiconductor chip 300 through the interconnection PCB 400, an extension part 401 configured to connect to an external driver circuit of the power semiconductor package structure is disposed on an edge of the interconnection PCB 400 on a side close to the right metal layer 206, and the extension part 401 connects the gate 302 and the source 301 of the power semiconductor chip to the external driver circuit.

As shown in FIG. 3, the interconnection PCB 400 includes an insulating substrate 402, a base plate connection part 420 is disposed on a back side of the interconnection PCB, the base plate connection part 420 is electrically connected to the left mounting platform 208 on the base plate 200, and a relatively high surface of a copper layer of the left metal layer 207 is used as an external interface of the power semiconductor package structure 100; and a power semiconductor chip connection part 422 interconnected with the source 301 of the power semiconductor chip is disposed on the back side of the interconnection PCB 400.

A base plate correspondence part 410 on a front side and the base plate connection part 420 on the back side of the interconnection PCB 400 are electrically connected to each other through a plurality of first conductive vias 421 (vias); a gate connection part 423 connected to the gate 302 is disposed on the back side of the interconnection PCB 400, and a back side conduction part 424 that conducts to the gate connection part 423 and a front side conduction part 412 that conducts to a source connection part 422 are disposed on the extension part 401; and a chip correspondence part 411 on the front side and a power semiconductor chip connection part 422 on the back side of the interconnection PCB 400 are electrically connected to each other through a plurality of second conductive vias.

A plurality of adhesive pouring holes 413 that run through a thickness direction of the interconnection PCB 400 to allow a sealing material of the package sealing layer 600 to penetrate into free space below the interconnection PCB 400 during packaging are disposed on the interconnection PCB 400.

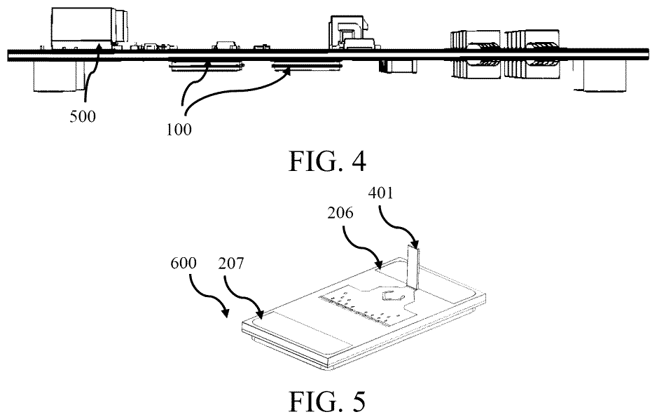

A protrusion part 401 of the interconnection PCB 400 configured to connect to the external driver circuit and top surfaces of the left metal layer 207 and the right metal layer 206 on two distal ends of the base plate are exposed out of the package sealing layer 600 to interconnect with an external main circuit, and may be directly connected to a circuit board 500 of a main circuit, as shown in FIG. 4.

This structure is not only applicable to a power semiconductor (for example, a SiC MOSFET) of a vertical structure, but also extensible to a power device of another type, for example, a device of a horizontal structure.

The foregoing embodiments are merely configured for exemplary description of the principles and effects of the present invention, and some of the applied embodiments of the present invention, and are not intended to limit the present invention. It should be noted that, a person of ordinary skill in the art may make various changes and improvements without departing from the creative ideas of the present invention, which shall all fall within the protection scope of the present invention.

1. A power semiconductor package structure, comprising a base plate, a power semiconductor chip, and an interconnection printed circuit board (PCB) connecting corresponding parts on the power semiconductor chipand the base plate; wherein a package sealing layer wrapping the power semiconductor chip and the interconnection PCB is disposed on the base plate;
the base plate comprises an intermediate insulation layer, an upper conductive metal layer of the base plate, and a lower conductive metal layer of the base plate; the lower conductive metal layer of the base plate is configured to connect to a heat sink; the upper conductive metal layer of the base plate comprises a left metal layer and a right metal layer that are physically separated by a separation slot and are electrically isolated; a sunken left mounting platform is disposed on a side of the left metal layer close to the separation slot, a sunken right mounting platform is disposed in a middle part of the right metal layer, the right mounting platform is configured for disposing the power semiconductor chip, and the interconnection PCB is mounted on the left mounting platform and the right mounting platform;
a drain of the power semiconductor chip is located at a bottom of the power semiconductor chip, and a source and a gate of the power semiconductor chip are located at a top of the power semiconductor chip; the drain of the power semiconductor chip is interconnected with the right mounting platform; the left metal layer is connected to the source of the power semiconductor chip through the interconnection PCB, an extension part configured to connect to an external driver circuit of the power semiconductor package structure is disposed on an edge of the interconnection PCB on a side close to the right metal layer, and the extension part connects the source and the gate of the power semiconductor chip to the external driver circuit;
the interconnection PCB comprises an insulating substrate, a base plate connection part is disposed on a back side of the interconnection PCB, the base plate connection part is electrically connected to the left mounting platform on the base plate, and a relatively high surface of a copper layer of the left metal layer is used as an external interface of the power semiconductor package structure; and a power semiconductor chip connection part interconnected with the source of the power semiconductor chip is disposed on the back side of the interconnection PCB;
a base plate correspondence part on a front side and the base plate connection part on the back side of the interconnection PCB are electrically connected to each other through a plurality of first conductive vias; a gate connection part connected to the gate is disposed on the back side of the interconnection PCB, and a chip correspondence part on the front side and a power semiconductor chip connection part on the back side of the interconnection PCB are electrically connected to each other through a plurality of second conductive vias; and
a protrusion part of the interconnection PCB and top surfaces of the left metal layer and the right metal layer on two distal ends of the base plate are exposed out of the package sealing layer to interconnect with an external main circuit.

2. The power semiconductor package structure according to claim 1, wherein a plurality of adhesive pouring holes that run through a thickness direction of the interconnection PCB to allow a sealing material of the package sealing layerto penetrate into free space below the interconnection PCB during packaging are disposed on the interconnection PCB.

3. The power semiconductor package structure according to claim 1, wherein a back side conduction part that conducts to the gate connection part and a front side conduction part that conducts to a source connection part are disposed on the extension part.
